(19) United States
(12) Patent Application Publication
(10) Pub. No.: US 2026/0026357 A1
(43) Pub. Date: Jan. 22, 2026

(54) SEMICONDUCTOR PACKAGE

(71) Applicant: Samsung Electronics Co., Ltd., Suwon-si (KR)

(72) Inventor: Seungwan SHIN, Suwon-si (KR)

(73) Assignee: Samsung Electronics Co., Ltd., Suwon-si (KR)

(21) Appl. No.: 19/024,824

(22) Filed: Jan. 16, 2025

(30) Foreign Application Priority Data
Jul. 19, 2024 (KR) 10-2024-0095953

(51) Int. Cl. H01L 23/544; H01L 23/00; H01L 23/498; H05K 1/02; H05K 1/11; H05K 1/18

(52) U.S. Cl. CPC H01L 23/544; H01L 23/49822; H01L 23/49838; H05K 1/0269; H05K 1/115; H05K 1/181; H01L 24/16; H01L 2223/54433; H01L 2224/16227; H01L 2924/1511; H05K 2201/042; H05K 2201/10734

(57) ABSTRACT

A semiconductor package includes a first semiconductor chip, a sealing layer molding the first semiconductor chip, and an upper connection structure on the sealing layer, wherein the upper connection structure includes an insulating layer. The insulating layer includes marking patterns defined by a first region and a second region, the first region being at at least a portion of the insulating layer and having a first light transmittance value, the second region being at at least a portion of the first region and having a second light transmittance value different from the first light transmittance value.

### CROSS-REFERENCE TO RELATED APPLICATION

This application is based on and claims priority under 35 U.S.C. § 119 to Korean Patent Application No. 10-2024-0095953, filed on Jul. 19, 2024, in the Korean Intellectual Property Office, the disclosure of which is incorporated by reference herein in its entirety.

### BACKGROUND

The inventive concepts relate to semiconductor packages and methods of manufacturing the same, and more particularly, to semiconductor packages including a photo imageable dielectric (PID) layer having a marking with higher identification.

For the purpose of identifying a semiconductor package, when a mark is left on the top surface of the semiconductor package, a clearer identification may be desired. However, when the upper insulating layer is transparent, the accuracy of the process of forming the mark may deteriorate, and the circuit region included in the semiconductor package may be affected by the laser forming the mark. Accordingly, a package technology that forms a mark more efficiently and increases the identification of the mark is being developed.

### SUMMARY

Provided are semiconductor packages with improved reliability and methods of manufacturing the same.

According to an example embodiment of the inventive concepts, a semiconductor package may include a first semiconductor chip, a sealing layer molding the first semiconductor chip, and an upper connection structure on the sealing layer, wherein the upper connection structure includes an insulating layer, the insulating layer including marking patterns defined by a first region and a second region, the first region being at at least a portion of the insulating layer and having a first light transmittance value, the second region being at at least a portion of the first region and having a second light transmittance value different from the first light transmittance value.

According to an example embodiment of the inventive concepts, a semiconductor package may include a first semiconductor chip, a sealing layer molding the first semiconductor chip, an upper connection structure to be vertically spaced apart from a top surface of the first semiconductor chip, a lower connection structure on a bottom surface of the first semiconductor chip and electrically connected to the first semiconductor chip, an external connection terminal under the lower connection structure, and an intermediate connection structure between the lower connection structure and the upper connection structure, wherein the upper connection structure includes an insulating layer, the insulating layer including marking patterns defined by a first region and a second region, the first region being at at least a portion of the insulating layer and having a first light transmittance value, the second region being at at least a portion of the first region and having a second light transmittance value different from the first light transmittance value, a length of the first region in a horizontal direction being greater than a length of the second region in the horizontal direction, a length of the first region in a vertical direction being different from a length of the second region in the vertical direction, and the lower connection structure includes at least one lower insulating layer, a lower redistribution pad on the lower insulating layer, and at least one lower via in contact with the lower redistribution pad.

According to an example embodiment of the inventive concepts, a semiconductor package may include a first semiconductor chip, a lower connection structure under the first semiconductor chip and electrically connected to the first semiconductor chip, a solder ball under the lower connection structure, a pad under the first semiconductor chip and electrically connected to the first semiconductor chip, a conductive post surrounding the first semiconductor chip, a sealing layer molding the first semiconductor chip and the conductive post, and an upper connection structure vertically spaced apart from a top surface of the first semiconductor chip, and an intermediate connection structure between the lower connection structure and the upper connection structure, wherein the upper connection structure includes an insulating layer, is the insulating layer being a photo imageable dielectric (PID) layer including transparent material, the insulating layer including masking patterns defined by a first region and a second region, the first region being at at least a portion of the insulating layer and having a first light transmittance value, the second region being at at least a portion of the first region and having a second light transmittance value different from the first light transmittance value, an upper semiconductor package is under the insulating layer, the upper semiconductor package including an uppermost connection structure and a second semiconductor chip on the uppermost connection structure, and an inter-package connection member electrically connects the upper semiconductor package with the upper connection structure.

### BRIEF DESCRIPTION OF THE DRAWINGS

Example embodiments will be more clearly understood from the following detailed description taken in conjunction with the accompanying drawings in which:

FIG. 1 is a cross-sectional view illustrating a semiconductor package according to an example embodiment;

FIG. 2 is an enlarged view of a region A of FIG. 1;

FIG. 3 is a cross-sectional view illustrating a semiconductor package according to another example embodiment;

FIG. 4 is a cross-sectional view illustrating a semiconductor package according to another example embodiment;

FIG. 5 is a cross-sectional view illustrating a semiconductor package according to another example embodiment; and

FIGS. 6 to 15 are cross-sectional views illustrating a process of manufacturing the semiconductor package shown in FIG. 1.

### DETAILED DESCRIPTION

Because example embodiments may be modified in various ways and may have various forms, some example embodiments are illustrated in the drawings and described in detail. However, it is not intended to limit the present example embodiments to the particular disclosed forms. In addition, the example embodiments described below are merely illustrative, and various modifications are possible from these example embodiments.

The use of all examples or example terms is merely intended to describe the technical idea in detail and is not intended to be limiting in scope by such examples or example terms, unless being limited by the claims.

Hereinafter, unless otherwise specified, in the present disclosure, a vertical direction may be defined in a Z direction, and a first horizontal direction and a second horizontal direction may be defined in horizontal directions perpendicular to the Z direction, respectively. The first horizontal direction may be referred to as X, and the second horizontal direction may be referred to as Y. A vertical level may refer to a height level according to the vertical direction Z. A horizontal width may refer to a length in the horizontal direction X and/or Y, and a vertical length may refer to a length in the vertical direction Z.

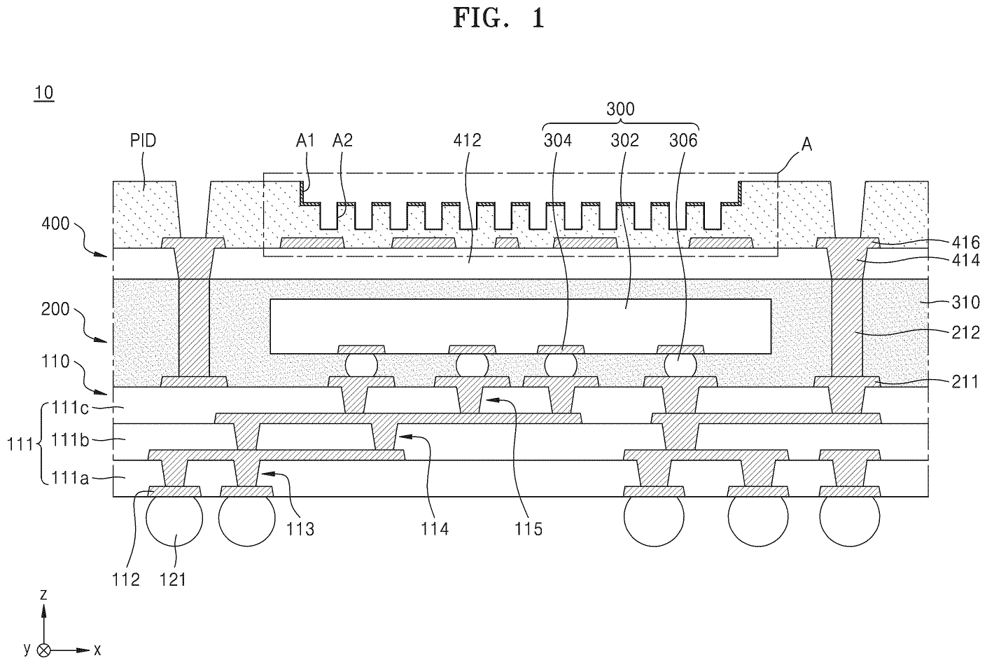

In claims of this application, a lower connection structure 110, an intermediate connection structure 200, and an upper connection structure 400, which are described below with reference to FIG. 1, may be simply referred to as a connection structure. Furthermore, lower insulating layers 111a, 111b, and 111c, an intermediate insulating layer, and an upper redistribution insulating layer 412 may simply be referred to as an insulating layer. In addition, lower vias, intermediate vias, and upper vias, which are described below with reference to FIG. 1, may simply be referred to as vias.

FIG. 1 is a cross-sectional view illustrating a semiconductor package according to an example embodiment.

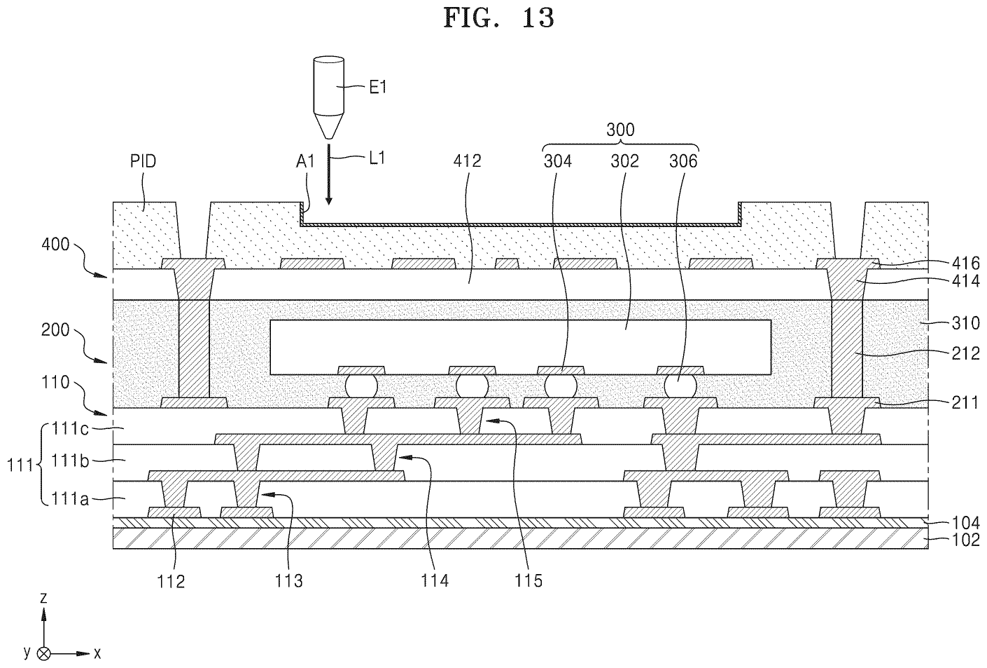

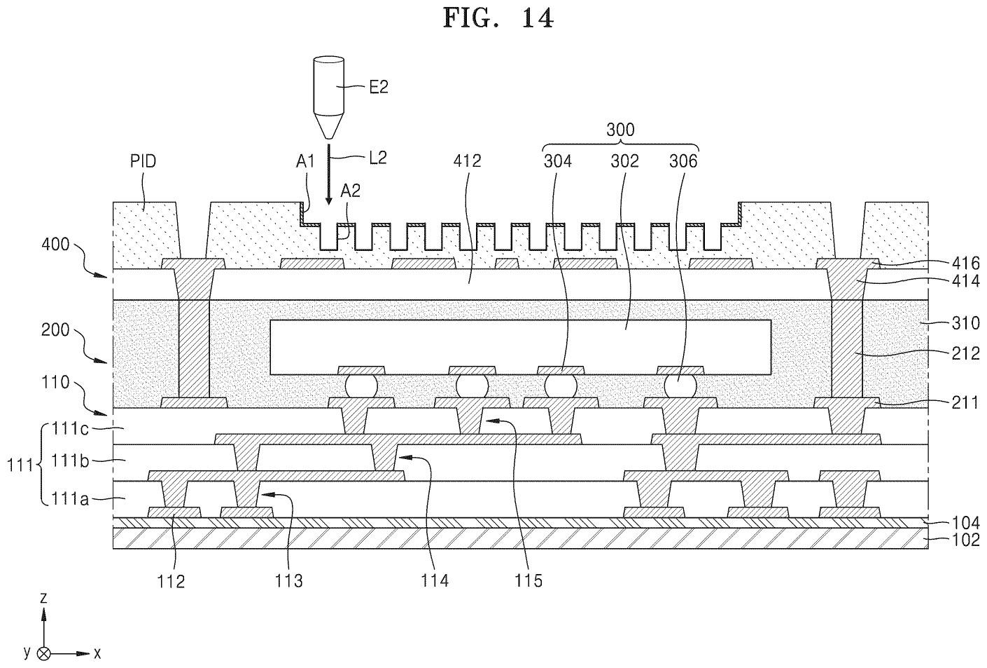

Referring to FIG. 1, a semiconductor package 10 may include a lower connection structure 110, a first semiconductor chip 300 on a top surface of the lower connection structure 110, an intermediate connection structure 200 on the top surface of the lower connection structure 110, and an upper connection structure 400 on the intermediate connection structure 200 and the first semiconductor chip 300. In some example embodiments, the semiconductor package 10 may further include a sealing layer 310 between the lower connection structure 110 and the upper connection structure 400. In some example embodiments, the semiconductor package 10 may further include external connection terminals 121 on a bottom surface of the lower connection structure 110. In some example embodiments, the upper connection structure 400 may include an insulating layer. The insulating layer may be formed in an upper portion region of the upper connection structure 400. In an example, the insulating layer may be a photo imageable dielectric (PID) layer PID made of a transparent material. Hereinafter, the insulating layer may simply be referred to as a PID layer PID. The semiconductor package 10 may include a first region A1 formed by a first laser at at least a portion of the PID layer PID, which is an insulating layer, and a second region A2 formed by a second laser at at least a portion of the first region A1. The first region A1 and the insulating layer may have different colors from each other. Descriptions of the first laser and the second laser will be given with reference to FIGS. 13 and 14.

The lower connection structure 110 may be configured to connect the first semiconductor chip 300 with the external connection terminal 121, to connect the intermediate connection structure 200 with the first semiconductor chip 300, and to connect the intermediate connection structure 200 with the external connection terminal 121. The lower connection structure 110 may include one or more lower insulating layers 111a, 111b, and 111c, lower redistribution pads arranged on the lower insulating layers, and at least one lower via in contact with the lower redistribution pads. The lower redistribution pads may be arranged on lower via arrays 113, 114, and 115, each of which includes a plurality of lower vias. In an example embodiment, the lower via may be configured to lengthily penetrate the lower insulating layer in the vertical direction, and the lower redistribution pad may be configured to lengthily penetrate the lower insulating layer in the horizontal direction while contacting the lower via. At least one lower redistribution pad and at least one lower via may provide an electrical path connecting the first semiconductor chip 300 with the external connection terminal 121, an electrical path connecting the intermediate connection structure 200 with the first semiconductor chip 300, and an electrical path connecting the intermediate connection structure 200 with the external connection terminal 121. The lower connection structure 110 may be a redistribution structure or a printed circuit board (PCB).

The lower connection structure 110 may include a first lower via array 113, a second lower via array 114, and a third lower via array 115 having different vertical levels. This will be described in detail below.

According to an embodiment, the first lower via array 113 may include a plurality of first lower vias arranged in a first direction (x direction). In this case, it was shown on the drawing that the first lower via array 113 includes five first lower vias, but example embodiments are not limited thereto. In some example embodiments, the first lower via array 113 may include five or more first lower vias. The first lower via array 113 may be formed through the first lower insulating layer 111a.

According to an example embodiment, the second lower via array 114 may include a plurality of second lower vias arranged in the first direction (x direction). In this case, it was shown on the drawing that the second lower via array 114 may include three second lower vias, but example embodiments are not limited thereto. According to some example embodiments, the second lower via array 114 may include three or more second lower vias. The second lower via array 114 may be formed through the second lower insulating layer 111b.

The lower connection structure 110 may include a first lower pad arranged at a vertical level between the first lower via array 113 and the second lower via array 114 to cover a top surface of the first lower via array 113. The first lower pad vertically overlaps one of more first lower vias of the first lower via array 113, and may cover top surfaces of the one ore more first lower vias of the first lower via array 113. The first lower pad may be integrally formed with of the one or more the first lower vias of the first lower via array 113.

According to an example embodiment, the third lower via array 115 may include a plurality of third lower vias arranged in the first direction (x direction). In this case, it was shown on the drawing that the third lower via array 115 includes five third lower vias, but example embodiments are not limited thereto. According to some example embodiments, the third lower via array 115 may include five or more third lower vias. The third lower via array 115 may be formed through the third lower insulating layer 111c.

The lower connection structure 110 may include a second lower pad arranged at a vertical level between the second lower via array 114 and the third lower via array 115 to cover a top surface of the second lower via array 114. The third lower pad vertically overlaps the second lower via array 114, and may cover top surfaces of one or more of the second lower vias of the second lower via array 114. The third lower pad may be integrally formed with the one or more of the second lower vias of the second lower via array 114.

The diameters of the first lower via of the first lower via array 113, the second lower via of the second lower via array 114, and the third lower via of the third lower via array 115 may decrease toward the external connection terminal 121. In other words, the cross-section of each of the first lower via, the second lower via, and the third lower via taken along the horizontal direction may decrease toward the ground. That is, the first lower via, the second lower via, and the third lower via may have a tapered shape.

The lower insulating layers 111a, 111b, and 111c may include, for example, an inorganic insulating material, an organic insulating material, or a combination thereof. The inorganic insulating material may include, for example, silicon oxide, silicon nitride, or a combination thereof. The organic insulating material may include, for example, polyimide, an epoxy resin, or a combination thereof. The plurality of pads and the plurality of lower vias buried in the lower insulating layers 111a, 111b, and 111c may include, for example, a conductive material that may include copper (Cu), gold (Au), silver (Ag), nickel (Ni), tungsten (W), aluminum (Al), or a combination thereof. In some example embodiments, the plurality of pads and the plurality of lower vias may further include a barrier material for blocking or preventing the conductive material from diffusing out of the plurality of pads and the plurality of lower vias. The barrier material may include, for example, titanium (Ti), tantalum (Ta), titanium nitride (TiN), tantalum nitride (TaN), or a combination thereof.

The first semiconductor chip 300 may include a body 302, and a plurality of chip pads 304 and a plurality of chip connection terminals 306 on a bottom surface of the body 302. The body 302 may include a substrate and integrated circuits on the substrate. The surface of the first semiconductor chip 300 on which the integrated circuit is formed may be referred to as an active surface, and the surface of the first semiconductor chip 300 facing the active surface may be referred to as an inactive surface. In FIG. 1, the active surface of the first semiconductor chip 300 may be a bottom surface of the first semiconductor chip 300, and the inactive surface of the first semiconductor chip 300 may be a top surface of the first semiconductor chip 300. The substrate may include a semiconductor material, for example, a group IV semiconductor material, a group III-V semiconductor material, a group II-VI semiconductor material, or a combination thereof. The group IV semiconductor material may include, for example, silicon (Si), germanium (Ge), or a combination thereof. The group III-V semiconductor material may include, for example, gallium arsenide (GaAs), indium phosphorus (InP), indium arsenide (InAs), indium antimony (InSb), indium gallium arsenide (InGaAs), or a combination thereof. The group II-VI semiconductor material may include, for example, zinc telluride (ZnTe), cadmium sulfide (CdS), or a combination thereof. The integrated circuit may be any type of integrated circuit including a memory circuit, a logic circuit, or a combination thereof. For example, the memory circuit may include a dynamic random access memory (DRAM) circuit, a static random access memory (SRAM) circuit, a flash memory circuit, an electrically erasable and programmable read-only memory (EEPROM) circuit, a phase-change random access memory (PRAM) circuit, a magnetic random access memory (MRAM) circuit, a resistive random access memory (RRAM) circuit, or a combination thereof. For example, the logic circuit may include a central processing unit (CPU) circuit, a graphic processing unit (GPU) circuit, a controller circuit, an application specific integrated circuit (ASIC), an application processor (AP) circuit, or a combination thereof.

The chip pad 304 may connect an integrated circuit of the body 302 to the lower connection structure 110. The chip pad 304 may include a conductive material which may include, for example, copper (Cu), gold (Au), silver (Ag), nickel (Ni), tungsten (W), aluminum (Al), or a combination thereof.

The chip connection terminal 306 may be arranged between the chip pad 304 included in the first semiconductor chip 300 and the lower connection structure 110 to connect the chip pad 304 and the lower connection structure 110 to each other. The semiconductor package 10 including the chip connection terminal 306 may have a chip last structure. The semiconductor package 10 shown in FIG. 1 may be a fan-out wafer level package (FOWLP).

The intermediate connection structure 200 may be positioned between the lower connection structure 110 and the upper connection structure 400 and may be configured to connect the lower connection structure 110 with the upper connection structure 400. The intermediate connection structure 200 may be located around the first semiconductor chip 300. That is, the intermediate connection structure 200 may surround the first semiconductor chip 300.

The intermediate connection structure 200 may include a conductive post 212 configured to connect the lower connection structure 110 with the upper connection structure 400. The intermediate connection structure 200 may include a first intermediate pattern 211 connected to a third lower via of the lower connection structure 110. The first intermediate pattern 211 and the conductive post 212 may provide an electrical path connecting the lower connection structure 110 with the upper connection structure 400.

The first intermediate pattern 211 and the conductive post 212 may include, for example, a conductive material which may include copper (Cu), gold (Au), silver (Ag), nickel (Ni), tungsten (W), aluminum (Al), or a combination thereof. In some example embodiments, the intermediate pattern 211 and the conductive post 212 may further include a barrier material for blocking or preventing the conductive material from diffusing out of the intermediate pattern 211 and the conductive post 212. The barrier material may include, for example, titanium (Ti), tantalum (Ta), titanium nitride (TiN), tantalum nitride (TaN), or a combination thereof.

The sealing layer 310 may cover a top surface of the first semiconductor chip 300 and surround the intermediate connection structure 200. The first sealing layer 310 may fill a space between the first semiconductor chip 300 and the upper connection structure 400. In some example embodiments, a space between the intermediate connection structure 200 and the first semiconductor chip 300 and a space between the lower connection structure 110 and the first semiconductor chip 300 may be at least partially further filled with the first sealing layer 310. The first sealing layer 310 may include, for example, a thermosetting resin such as an epoxy resin, a thermoplastic resin such as polyimide, or a resin including an inorganic filler in the thermosetting resin and the thermoplastic resin (e.g., ajinomoto build-up film (ABF), flame retardant (FR)-4, bismaleimide triazine (BT), or the like). In addition, molding materials such as epoxy mold compound (EMC) or photosensitive materials may be used as the first sealing layer 310.

The upper connection structure 400 may be configured to be connected to the intermediate connection structure 200. The upper connection structure 400 may include an upper redistribution insulating layer 412 on the sealing layer 310, an upper redistribution pad 416 on the upper redistribution insulating layer 412, and an upper redistribution via 414 extending between the conductive post 212 and the upper redistribution pad 416 and through the upper redistribution insulating layer 412. The upper connection structure 400 may be a redistribution structure.

A plurality of upper redistribution pads 416 may be provided. Some of the plurality of upper redistribution pads 416 may be grounded, and some others of the plurality of upper redistribution pads 416 may be configured to transmit a signal. By grounding at least some of the upper redistribution pads 416, characteristics (e.g., signal integrity) of signals and power characteristics (e.g., power integrity) transmitted through other upper redistribution pads 416 may be improved.

The upper redistribution pad 416 and the upper redistribution via 414 may include a conductive material which may include, for example, copper (Cu), gold (Au), silver (Ag), nickel (Ni), tungsten (W), aluminum (Al), or a combination thereof. In some example embodiments, the upper redistribution pad 416 and the upper redistribution via 414 may further include a barrier material for blocking or preventing the conductive material from diffusing out of the upper redistribution pad 416 and the upper redistribution via 414. The barrier material may include, for example, titanium (Ti), tantalum (Ta), titanium nitride (TiN), tantalum nitride (TaN), or a combination thereof.

In an example embodiment, a PID layer PID may be arranged on an upper portion of the upper connection structure 400. The PID layer PID may be an insulating layer. The PID layer PID may cover a portion of the top surface of the upper redistribution pad 416. A partial area of the upper redistribution pad 416 not covered by the PID layer PID may be exposed. A first region A1 and a second region A2 may be formed on a top surface of the PID layer PID. The first region A1 may be formed at at least a portion of a region formed by the PID layer PID. The second region A2 may be formed at at least a portion of the first region A1 formed by the PID layer PID. The second region A2 may be formed at at least a portion of a region formed by the first region A1. The second region A2 may be formed after the first region A1 is formed, and both the first region A1 and the second region A2 may be formed in the form of a groove in a portion of the PID layer PID. The groove formed by each of the first region A1 and the second region A2 may not interfere with the upper redistribution pad 416. That is, the top surface of the upper redistribution pad 416 is not exposed by the groove shape formed by the first region A1 or the second region A2. The first region A1 and the second region A2 may have different colors from each other. In an example embodiment, the first region A1 may be formed in black. In an example embodiment, the second region A2 may be formed in white. In an example embodiment, the first region A1 may be formed at a lower brightness than the second region A2.

The first region A1 and the second region A2 have different colors and therefore different light transmittance values from each other. Thus, the first region A1 and the second region A2 may be identified from each other. The meaning of identification here means that identification is possible with the naked eye. Through the identified features, the first region A1 and the second region A2 may constitute marking patterns. The marking pattern may be used to identify a semiconductor package.

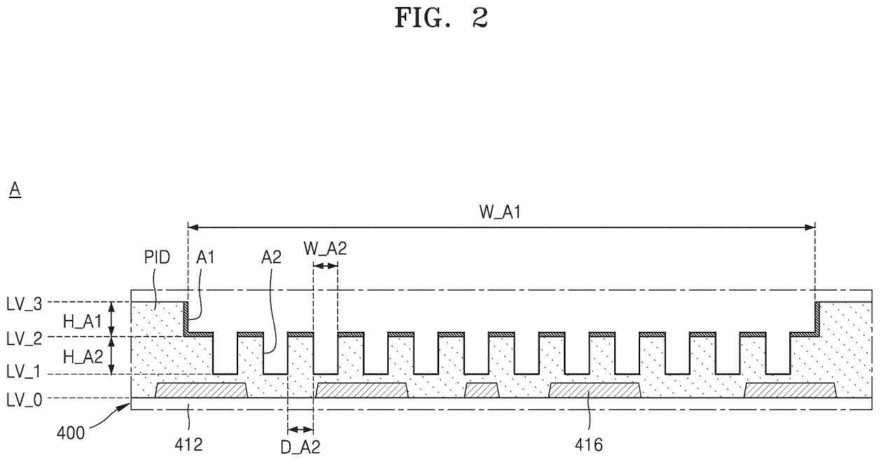

FIG. 2 is an enlarged view of a region A of FIG. 1.

Description is made with reference to FIG. 2 together with FIG. 1. The first region A1 may have a length as long as W_A1 in the horizontal direction. The first region A1 may have a length as long as H_A1 in the vertical direction. That is, the first laser forming the first region A1 may be irradiated while moving by the length of H_A1. The second region A2 may have a length as long as W_A2 in the horizontal direction. The second region A2 may be formed as a plurality of grooves within the range of the first region A1. The length W_A1 of the first region A1 in the horizontal direction may be greater than the length W_A2 of the second region A2 in the horizontal direction. That is, the second region A2 may be surrounded by the first region A1. The second region A2 may have a length as long as H_A2 in the vertical direction. The length H_A1 of the first region A1 in the vertical direction may be different from the length H_A2 of the second region A2 in the vertical direction. The grooves formed by the second region A2 may be formed to be spaced apart from each other by the length of D_A2, respectively. However, in the drawing, each groove formed by the second region A2 is shown to have a regular interval, but the spacing of each groove formed by the second region A2 may be different.

Hereinafter, a vertical level of each component is described in detail. A vertical level at a lowermost end of the PID layer PID, which is an insulating layer, is referred to as LV_0. A lowermost level of the second region A2 is referred to as LV_1. A lowermost level of the first region A1 is referred to as LV_2. The uppermost level of the PID layer PID is referred to as LV_3. When LV_0, LV_1, LV_2, and LV_3 are compared, LV_0 may be the lowest vertical level. LV_2, which is the lowermost level of the first region A1, may be lower than LV_3, which is the level of the top surface of the PID layer PID. That is, the first region A1 may be formed while etching a portion of the region of the PID layer PID. LV_1, which is the lowermost level of the second region A2, may be lower than LV_2, which is the lowermost level of the first region A1. That is, the second region A2 may be formed while etching a portion of the region of the PID layer PID within a range in which the first region A1 is formed. The first region A1 and the second region A2 may not be formed at the same time. The first region A1 may be formed earlier than the second region A2. The second region A2 may be formed in a partial region of the top surface of the PID layer PID, and the second region A2 may not be formed at a position other than the first region A1.

In the drawings, both side walls of the first region A1 and the second region A2 are illustrated vertically, but the shape of the side wall or the shape of the groove may be different from the shape of the drawing. That is, the first region A1 and the second region A2 may have an inverted triangular shape or a tapered shape in which widths become narrower as the first region A1 and the second region A2 descend in the vertical direction. In one example embodiment, the first region A1 and the second region A2 may have a semicircular shape.

The PID layer PID may include a transparent material. When marking a conventional PID layer PID, the laser may be transmitted and visibility may be lowered due to the transparent properties of the PID layer PID. According to some example embodiments of the inventive concepts, the first region A1 having black color is first formed on the top surface of the PID layer PID made of a transparent material. The second region A2 having white color is formed with respect to a portion of the top surface of the formed first region A1, to provide a feature in which visibility is improved. The black first region A1 may constitute a background of the marking pattern. The white second region A2 may constitute a type engraved on the marking pattern.

The external connection terminal 121 may be positioned on a bottom surface of the first lower pad 112 of the lower connection structure 110. The external connection terminal 121 may include, for example, a conductive material such as tin (Sn), lead (Pb), silver (Ag), copper (Cu), or a combination thereof. The external connection terminal 121 may be formed using, for example, a solder ball. The external connection terminal 121 may connect the semiconductor package 10 to a circuit board, another semiconductor package, an interposer, or a combination thereof.

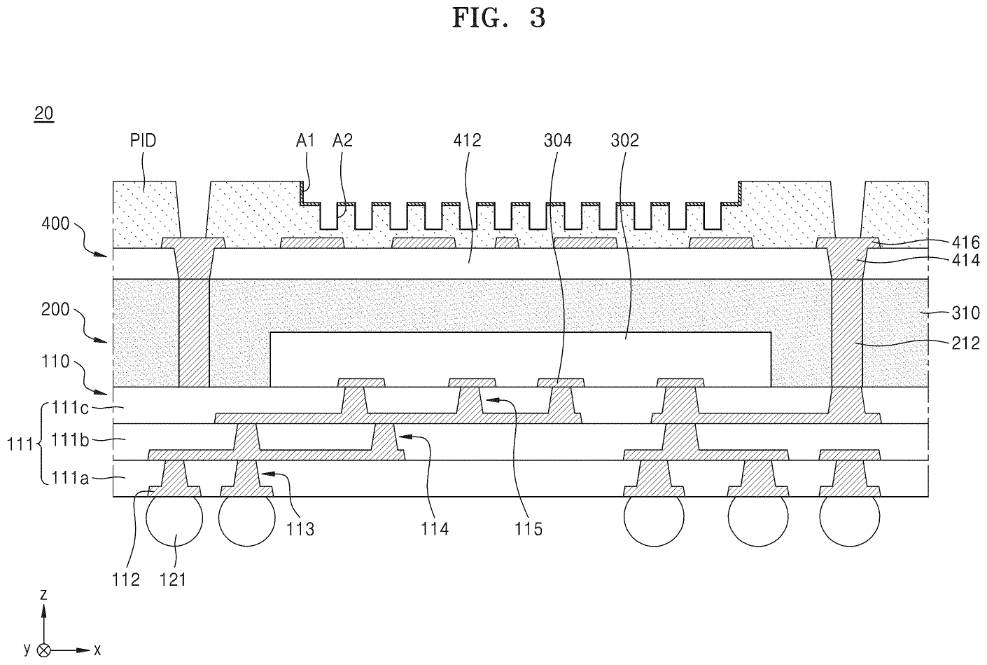

FIG. 3 is a cross-sectional view illustrating a semiconductor package according to another example embodiment.

The semiconductor package 20 illustrated in FIG. 3 may have a chip-first structure. The semiconductor package 20 illustrated in FIG. 3 may be a fan-out wafer level package (FOWLP) similar to the semiconductor package 10 illustrated in FIG. 1.

The semiconductor package 20 shown in FIG. 3 may be almost the same or similar as the semiconductor package 10 shown in FIG. 1 except that there is no chip connection terminal and there is a difference in the structure of the lower via arranged on the lower connection structure 110. Therefore, hereinafter, the semiconductor package 20 shown in FIG. 3 may be almost the same or similar as the semiconductor package 10 shown in FIG. 1 except that the structure of the intermediate connection structure 200 is different. Therefore, the structure of the lower via arrays is mainly described below.

The third lower via array 115 may be in contact with the chip pad 304 to be electrically connected. Each of the first lower via array 113, the second lower via array 114, and the third lower via array 115 shown in FIG. 3 may include a plurality of lower vias in the same manner as shown in FIG. 1. The cross-section, in the horizontal direction, of each of the first lower via included in the first lower via array 113, the second lower via included in the second lower via array 114, and the third lower via included in the third lower via array 115 may increase toward the ground. That is, the tapered shape of FIG. 3 may be formed in an opposite direction to the tapered shape of FIG. 1. However, even in the case of the chip first structure, the cross-section of the upper redistribution via 414 in the horizontal direction may decrease toward the ground, as shown in FIG. 1.

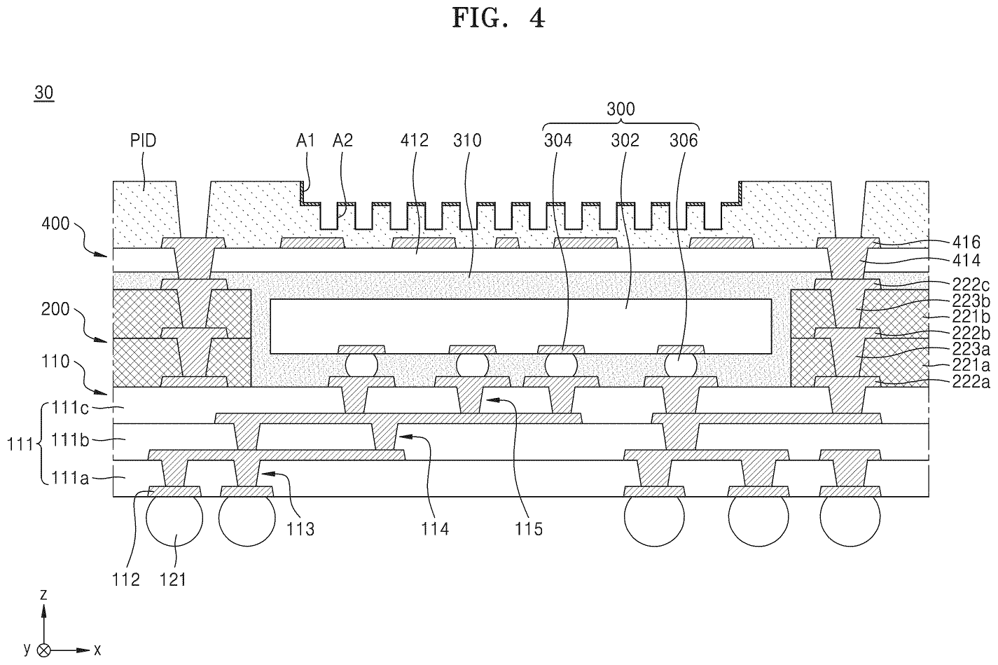

FIG. 4 is a cross-sectional view illustrating a semiconductor package according to another example embodiment.

The semiconductor package 30 shown in FIG. 4 may be a fan-out panel level package (FOPLP). The semiconductor package 30 may have a chip last structure. The semiconductor package 30 illustrated in FIG. 4 may be almost the same or similar as the semiconductor package 10 illustrated in FIG. 1 and the semiconductor package 20 illustrated in FIG. 3 except that the intermediate connection structure 200 has different structures. Therefore, hereinafter, the structure of the intermediate connection structure 200 is mainly described.

The intermediate connection structure 200 may include one or more intermediate vias 223a and 223b configured to connect the lower connection structure 100 with the upper connection structure 400.

In some example embodiments, the intermediate connection structure 200 may further include one or more intermediate insulating layers 221a and 221b through which the one or more intermediate vias 223a and 223b pass. In some example embodiments, the intermediate connection structure 200 may further include a plurality of intermediate pattern layers 222a, 222b, and 222c buried in the one or more intermediate insulating layer 221a and 221b, or arranged on the intermediate insulating layers 221a and 221b, and connected to each other by the one or more intermediate vias 223a and 223b. The one or more intermediate vias 223a and 223b and the plurality of intermediate pattern layers 222a, 222b and 222c may provide an electrical path connecting the lower connection structure 110 with the upper connection structure 400.

In an example embodiment, the intermediate connection structure 200 may include a first intermediate pattern layer 222a on the top surface of the lower connection structure 110, and a first intermediate insulating layer 221a on the top surface of the first intermediate pattern layer 222a and the top surface of the lower connection structure 110.

In an example embodiment, the intermediate connection structure 200 may include a first intermediate via 223a penetrating the first intermediate insulating layer 221a and contacting the upper surface of the first intermediate pattern layer 222a, a second intermediate pattern layer 222b on the top surface of the first intermediate via 223a and the top surface of the first intermediate insulating layer 221a, and a second intermediate insulating layer 221b on the top surface of the second intermediate pattern layer 222b and the first intermediate insulating layer 221a.

In an example embodiment, the intermediate connection structure 200 may include a second intermediate via 223b penetrating the second intermediate insulating layer 221b and contacting the top surface of the second intermediate pattern layer 222b, and a third intermediate pattern layer 222c on the top surface of the second intermediate via 223b and the top surface of the second intermediate insulating layer 221b. However, unlike shown in FIG. 4, the intermediate connection structure 200 may include more or fewer conductive pattern layers than three.

The first intermediate via 223a may connect the first intermediate pattern layer 222a with the second intermediate pattern layer 222b, and the second intermediate via 223b may connect the second intermediate pattern layer 222b with the third intermediate pattern layer 222c. The first intermediate pattern layer 222a may be in contact with the first lower via of the lower connection structure 110, and the third intermediate pattern layer 222c may be in contact with the upper redistribution via 414 of the upper connection structure 400.

Features or materials constituting the plurality of intermediate pattern layers 222a, 222b, and 222c, the plurality of intermediate vias, and the plurality of intermediate insulating layers 222, which are illustrated in FIG. 4, may be substantially the same as those of the plurality of intermediate patterns 211, conductive posts 212, and intermediate insulating layers 222, which are described with reference to FIGS. 1 to 3.

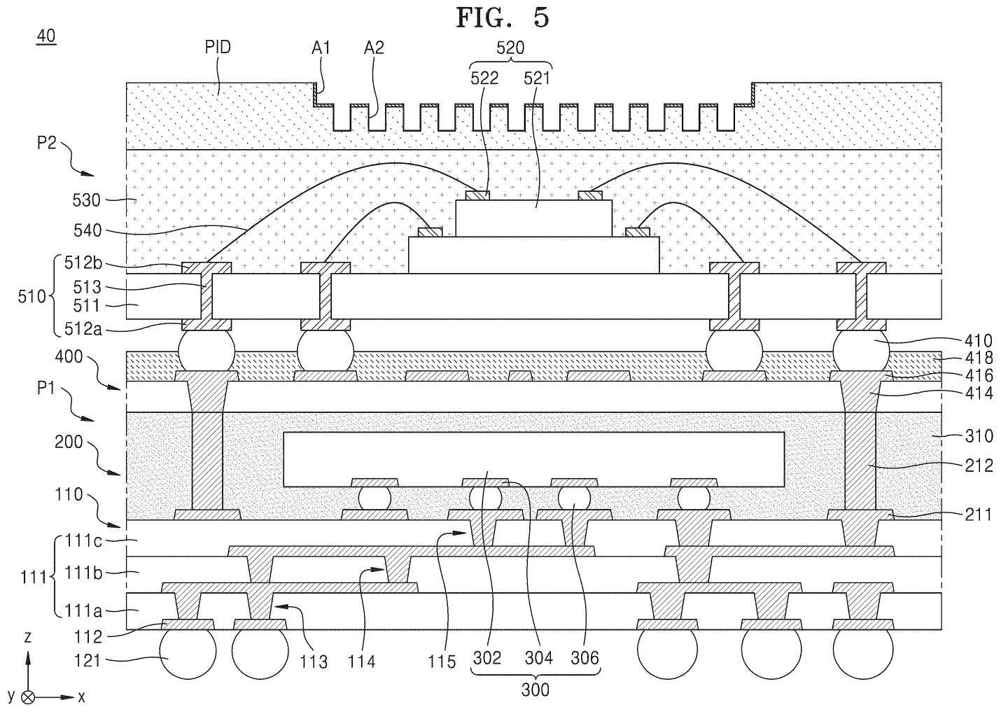

FIG. 5 is a cross-sectional view illustrating a semiconductor package according to another example embodiment.

Referring to FIG. 5, a semiconductor package 40 may include a lower semiconductor package P1, an upper semiconductor package P2 on the lower semiconductor package P1, and an inter-package connection member 410 between the lower semiconductor package P1 and the upper semiconductor package P2. That is, the semiconductor package 40 may be a package on package (POP) type. The lower semiconductor package P1 may be the semiconductor package 10 shown in FIG. 1. The upper semiconductor package P2 may be arranged under the PID layer PID, which is an insulating layer.

The upper semiconductor package P2 may include an uppermost connection structure 510 and a second semiconductor chip 520 on the uppermost connection structure 510. In some example embodiments, the upper semiconductor package P2 may include a plurality of second semiconductor chips 520 stacked on the uppermost connection structure 510. In some example embodiments, the upper semiconductor package P2 may further include a second sealing layer 530 covering the uppermost connection structure 510 and the second semiconductor chip 520. The upper semiconductor package P2 may be arranged between the upper connection structure 400 and the PID layer PID. That is, the PID layer PID of FIGS. 1 to 4 is formed to cover a portion of the top surface of the upper connection structure 400, but the PID layer PID of FIG. 5 may be formed to cover a portion of the top surface of the upper semiconductor package P2. The shape and material of the PID layer PID of FIG. 5 may correspond to the PID layer PID described with reference to FIGS. 1 to 4.

The uppermost connection structure 510 may include, for example, an insulating layer 511, an upper conductive pattern layer 512b on a top surface of the insulating layer 511, a lower conductive pattern layer 512a on a bottom surface of the insulating layer 511, and a via 513 extending between the upper conductive pattern layer 512b and the lower conductive pattern layer 512a through the insulating layer 511 to connect the upper conductive pattern layer 512b with the lower conductive pattern layer 512a. The uppermost connection structure 510 may be a printed circuit board (PCB) or a redistribution structure. For example, the insulating layer 511 may include FR-4, tetrafunctional epoxy, polyphenylene ether, epoxy/polyphenylene oxide, BT, thermount, cyanate ester, polyimide, or a combination thereof. The upper conductive pattern layer 512b, the lower conductive pattern layer 512a, and the via 513 may include a conductive material that may include, for example, copper (Cu), gold (Au), silver (Ag), nickel (Ni), tungsten (W), aluminum (Al), or a combination thereof.

The second semiconductor chip 520 may include a body 521 and a chip pad 522 on a top surface of the body 521. The body 521 may include a substrate and an integrated circuit, and the integrated circuit may be positioned on a top surface of the second semiconductor chip 520. That is, the active surface of the second semiconductor chip 520 may be a top surface of the second semiconductor chip 520. The second semiconductor chip 520 may be connected to the upper conductive pattern layer 512b of the uppermost connection structure 510 through wires 540. In another example embodiment, the chip pad 522 of the second semiconductor chip 520 may be located on the bottom surface of the second semiconductor chip 520, and the integrated circuit of the body 521 of the second semiconductor chip 520 may be located on the bottom surface of the second semiconductor chip 520. That is, the active surface of the second semiconductor chip 520 may be a bottom surface of the second semiconductor chip 520. The second semiconductor chip 520 may be connected to the upper conductive pattern layer 512b of the uppermost connection structure 510 through bumps or pillars.

The second semiconductor chip 520 may be a memory chip or a logic chip. The memory chip may be, for example, a volatile memory chip such as dynamic random access memory (DRAM) or static random access memory (SRAM), or may be a nonvolatile memory chip such as a phase-change random access memory (PRAM), a magnetoresistive random access memory (MRAM), ferroelectric random access memory (FeRAM), or resistive random access memory (RRAM). The logic chip may be a central processing unit (CPU) chip, a graphics processing unit (GPU) chip, an application processor (AP) chip, or an application specific integrated circuit (ASIC) chip.

In some example embodiments, the integrated circuit of the body 302 of the first semiconductor chip 300 of the lower semiconductor package P1 may include a logic circuit, and the integrated circuit of the body 521 of the second semiconductor chip 520 of the upper semiconductor package P2 may include a memory circuit. The second sealing layer 530 may include, for example, epoxy resin, silicone resin, or a combination thereof. The second sealing layer 530 may include, for example, epoxy mold compound.

The inter-package connection member 410 is positioned between the lower conductive pattern layer 512a of the uppermost connection structure 510 of the upper semiconductor package P2 and the upper redistribution pad 416 of the upper connection structure 400 of the lower semiconductor package P1, and may connect the lower conductive pattern layer 512a of the uppermost connection structure 510 of the upper semiconductor package P2 with the upper redistribution pad 416 of the upper connection structure 400 of the lower semiconductor package P1. The upper protective layer 418 of the lower semiconductor package P1 may expose a portion of the upper redistribution pad 416 in contact with the inter-package connection member 410 and cover the remaining portion of the upper redistribution pad 416. The inter-package connection member 410 may include a conductive material including, for example, tin (Sn), lead (Pb), silver (Ag), copper (Cu), or a combination thereof. The inter-package connection member 410 may be formed from, for example, solder balls.

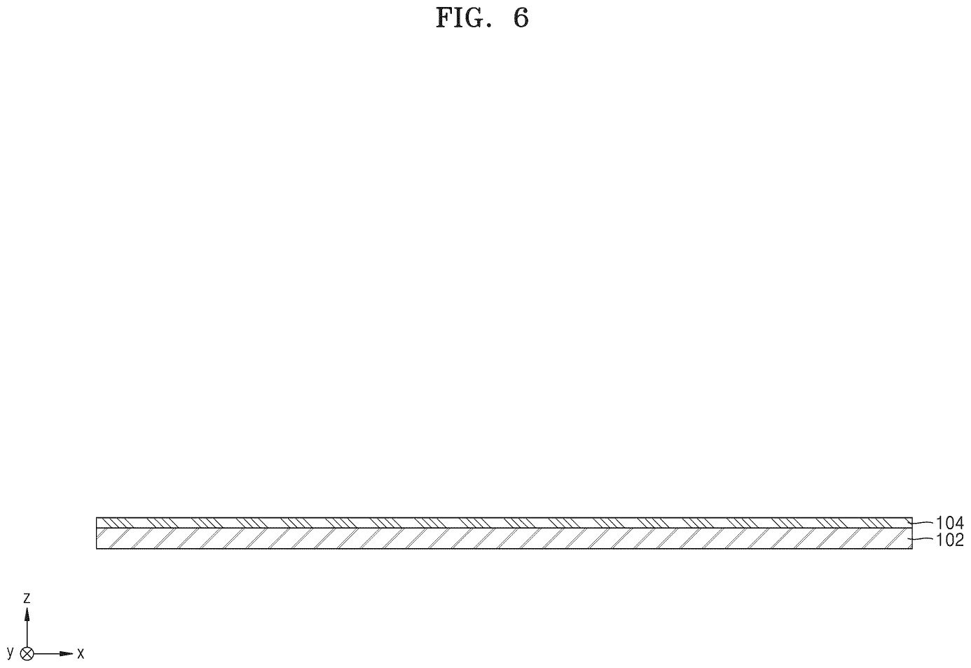

FIGS. 6 to 15 are cross-sectional views illustrating a process of manufacturing the semiconductor package shown in FIG. 1.

Referring to FIG. 6, a method of manufacturing a semiconductor package 10 according to an example embodiments of the inventive concepts may include providing a carrier substrate 102 to which a release film 104 is attached.

The carrier substrate 102 may include any material having stability in a baking process and an etching process. When the carrier substrate 102 is to be separated and removed by laser ablation in a later operation, the carrier substrate 102 may be a transmissive substrate. Optionally, when the carrier substrate 102 is to be separated and removed by heating later, the carrier substrate 102 may be a heat-resistant substrate.

In an example embodiment, the carrier substrate 102 may be a glass substrate. In another embodiment, the carrier substrate 102 may include a heat-resistant organic polymer material such as polyimide (PI), polyether etherketone (PEEK), polyethersulfone (PES), polyphenylene sulfide (PPS), or the like, but example embodiments are not limited thereto.

The release film 104 may be, for example, a laser reaction layer that may allow the carrier substrate 102 to be detachable by vaporization in response to laser irradiation later. The release film 104 may include a carbon-based material layer. For example, the release film 104 may include an amorphous carbon layer (ACL).

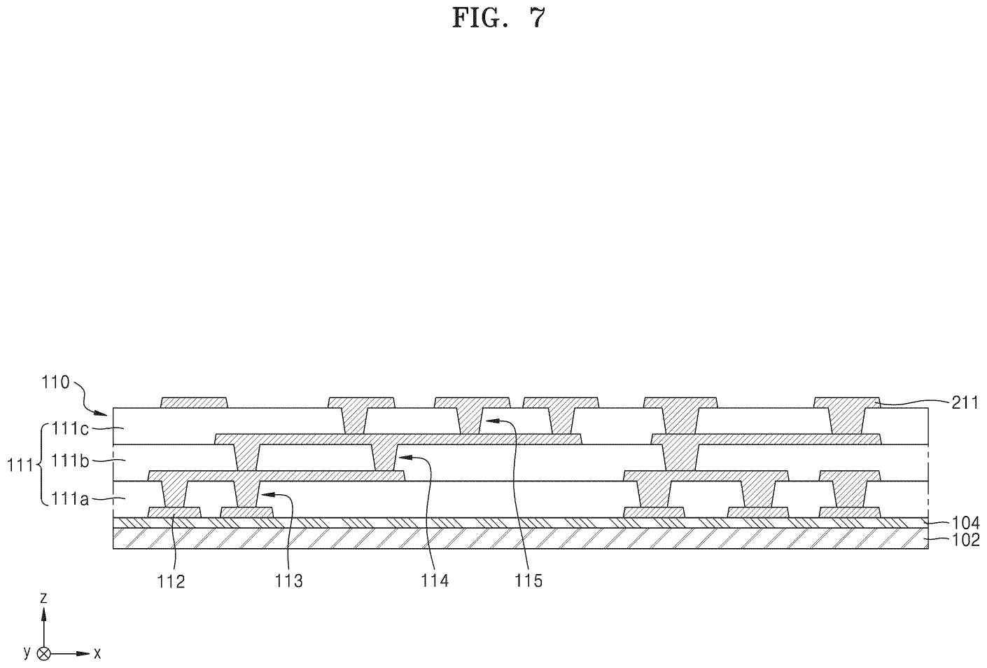

Referring to FIG. 7, the method of manufacturing the semiconductor package 10 according to an example embodiments of the inventive concepts may include forming the lower connection structure 110 on the carrier substrate 102 to which the release film 104 is attached. A plurality of lower via arrays 113, 114, and 115 may be formed by a deposition process or a plating process after forming holes in the lower insulating layers 111a, 111b, and 111c. The deposition process may be a process selected from physical vapor deposition (PVD), chemical vapor deposition (CVD), or atomic layer deposition (ALD).

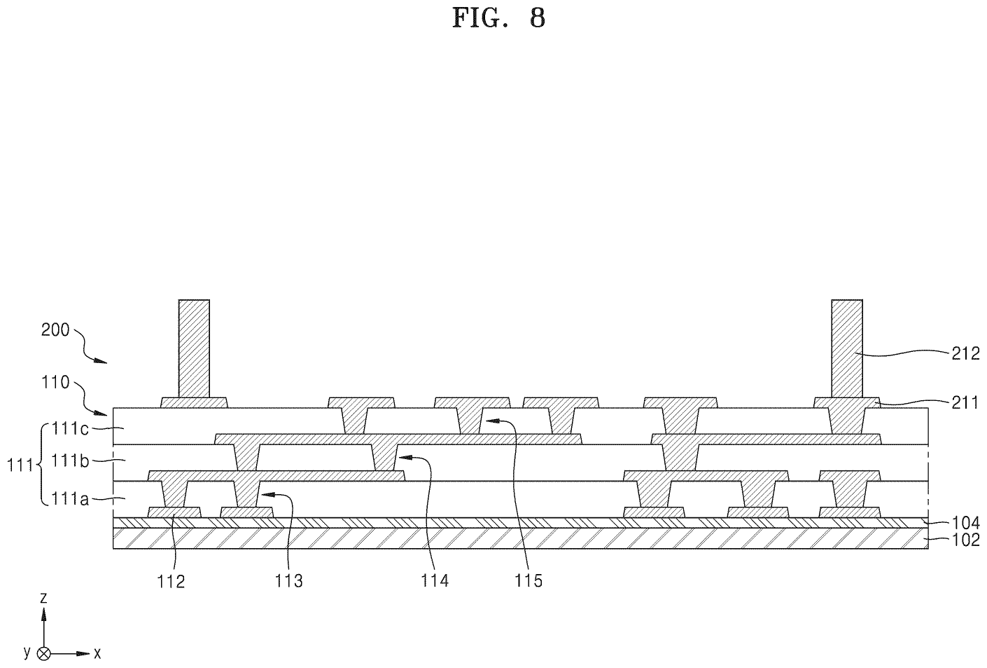

Referring to FIG. 8, the method of manufacturing the semiconductor package 10 of an example embodiments of the inventive concepts may include forming the intermediate connection structure 200 on the lower connection structure 110. The conductive post 212 may be arranged on the lower connection structure 110. In an example embodiment, the conductive post 212 may be arranged to surround a space in which the first semiconductor chip 300 is to be arranged.

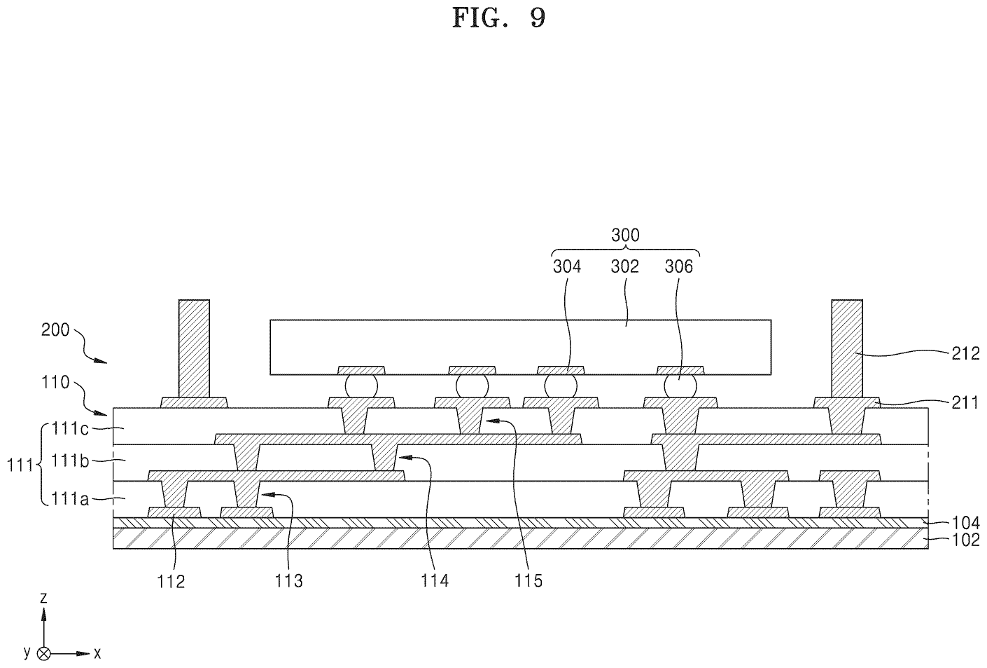

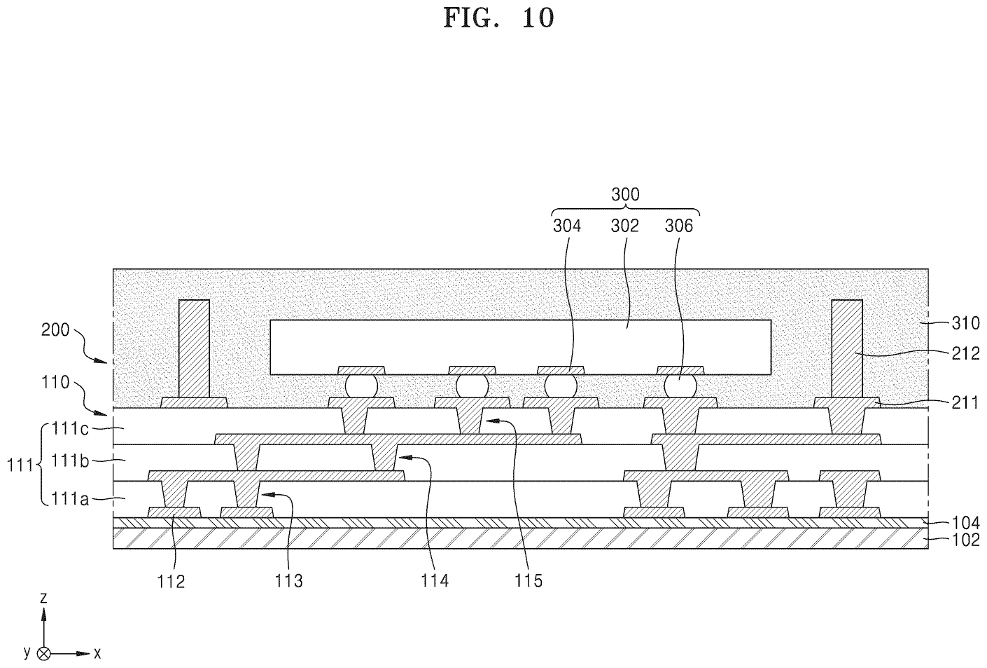

Referring to FIGS. 9 and 10, the method of manufacturing the semiconductor package 10 according to an example embodiments of the inventive concepts may include attaching the first semiconductor chip 300 (e.g., the chip pads 304 or the chip connection terminal 306) onto the first intermediate pattern 211. Thereafter, a first sealing layer 310 covering the first semiconductor chip 300 and the intermediate connection structure 200 may be formed. The first sealing layer 310 may be formed by a known method. For example, the first sealing layer 310 may be formed by laminating the sealing material on the top surface of the first semiconductor chip 300 and the top surface of the intermediate connection structure 200 and then curing the sealing material.

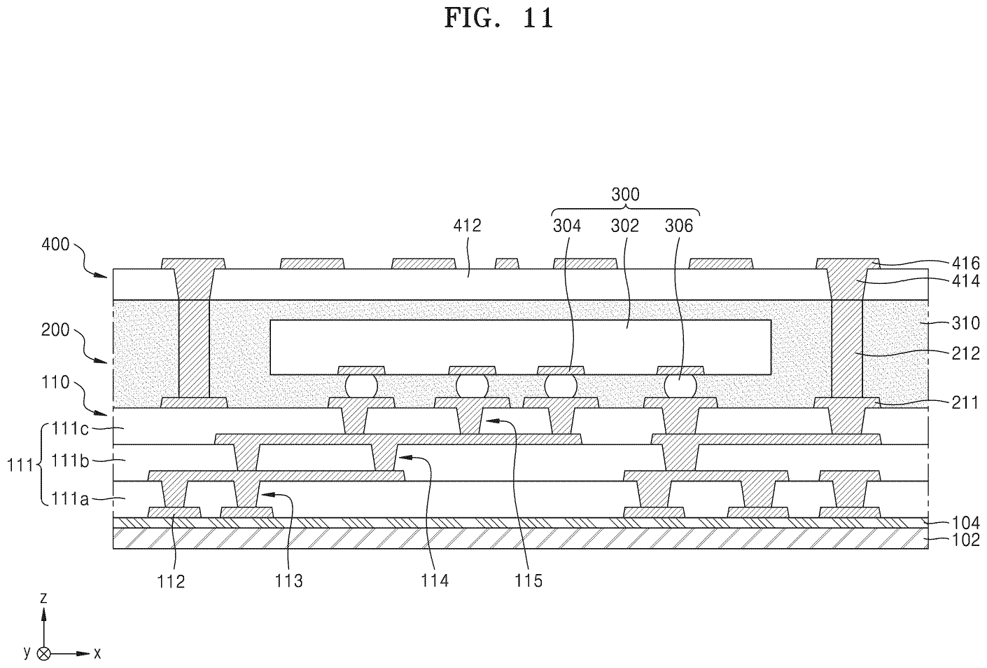

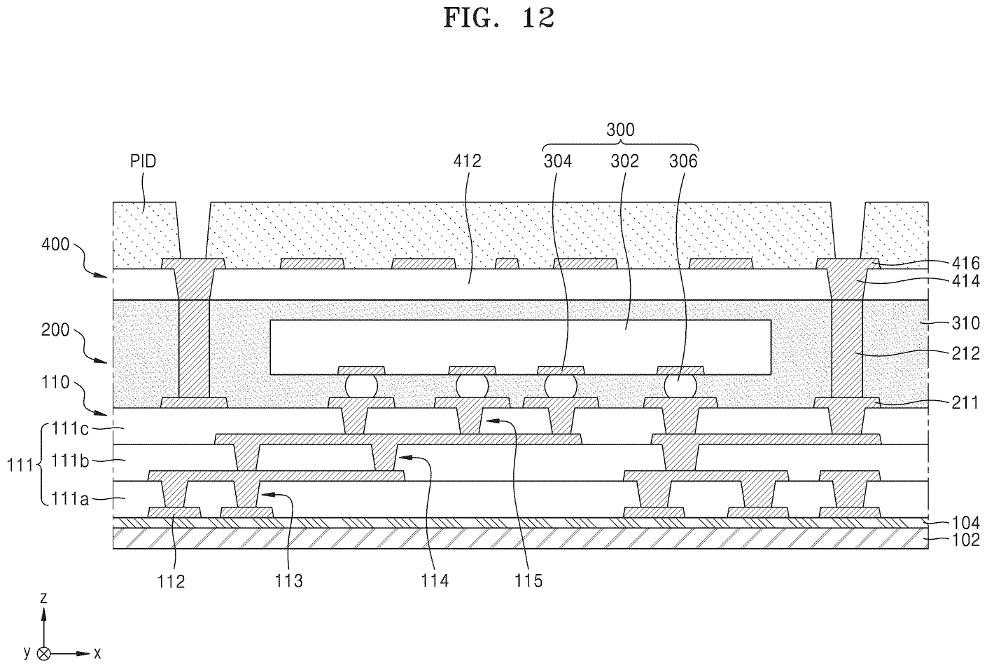

Referring to FIGS. 11 and 12, the method of manufacturing the semiconductor package 10 according to an example embodiment of the inventive concepts may include forming an upper connection structure 400 on the first sealing layer 310 and forming a PID layer PID on a top surface of the upper connection structure 400. The PID layer PID may include a transparent material or a translucent material. After the PID layer PID is conformally formed on the top surface of the upper connection structure 400, etching may be performed on a partial region. The partial region in which the etching is performed may be a top surface of the upper redistribution pad 416. In other words, not an entire area of the top surface of the upper redistribution pad 416 may be etched. That is, the PID layer PID may cover only a portion of the top surface of the upper redistribution pad 416. The PID layer PID may be conformally formed so that the vertical level is constant except for a region to be etched.

Although the thickness of the PID layer PID in the vertical direction is shown to be thicker than the thickness of the upper redistribution pad 416 in the vertical direction, the thickness of the PID layer PID in the vertical direction is not limited thereto. In an example embodiment, the thickness of the PID layer PID in the vertical direction may be equal to or less than the thickness of the upper redistribution pad 416 in the vertical direction.

Referring to FIG. 13, the method of manufacturing the semiconductor package 10 of an example embodiment of the inventive concepts may include forming the first region A1 by the first laser L1 emitted from a first emitter E1 at at least a portion of the PID layer PID. The first laser L1 may etch a portion of the PID layer PID. The first laser L1 may move in the horizontal direction and form the first region A1. The portion etched by the first laser L1 may correspond to the first region A1. Although the shape of the first part A1 is illustrated in a rectangular shape including a right angle in the drawings, the shape of the first part A1 may not be limited thereto. In an example embodiment, the shape of the first region A1 may be a trapezoidal shape in which the sidewalls are inclined or a shape in which the sidewalls are rounded.

Referring to FIG. 14, the method of manufacturing the semiconductor package 10 of an example embodiment of the inventive concept may include forming the second region A2 by the second laser L2 emitted from a second emitter E2 at at least a portion of the first region A1. The first region A1 and the second region A2 may integrally form marking patterns. A wavelength of the second laser L2 forming the second region A2 may be longer than that of the first laser L1 forming the first region A1. The first region A1 formed by the first laser L1 and the second region A2 formed by the second laser L2 may have different colors from each other.

The second regions A2 may be spaced apart from each other at regular intervals in the first region A1 to have an uneven shape.

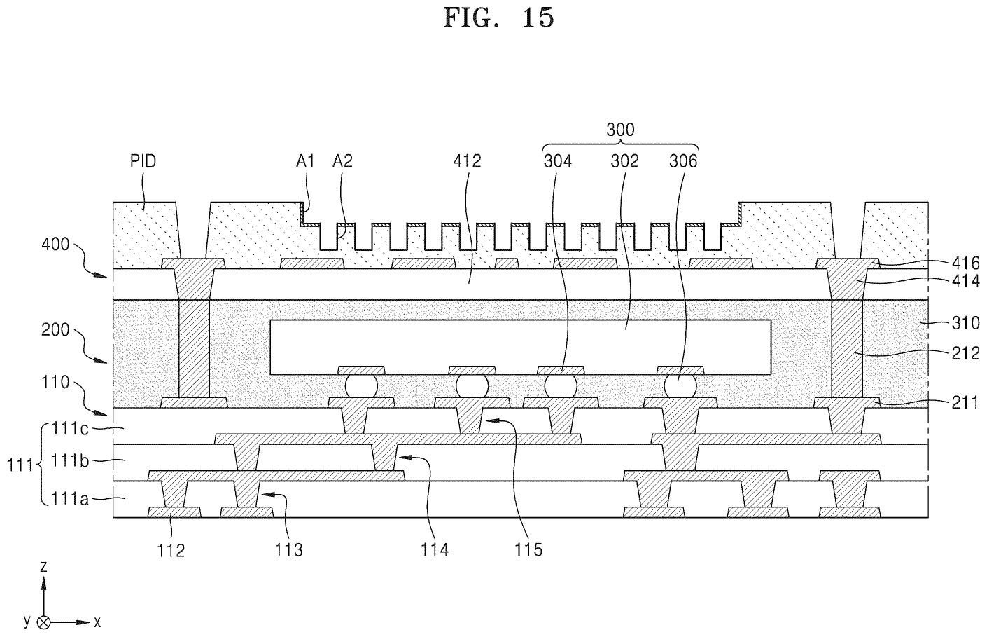

Referring to FIG. 15, the method of manufacturing the semiconductor package 10 of an example embodiment of the inventive concepts may include removing the carrier substrate 102 and the release film 104 to attach the external connection terminal 121 to the first lower pad 112 of the lower connection structure 110. The carrier substrate 102 to which the release film 104 is attached may be separated. For example, to separate the carrier substrate 102, the release film 104 may be irradiated with a laser or heated. Referring to FIG. 15 together with FIG. 1, after the carrier substrate 102 is separated, an external connection terminal 121 may be attached to the exposed first lower pad 112 to form the semiconductor package 10 of FIG. 1. The external connection terminal 121 may be, for example, a solder ball or a bump.

While the inventive concepts have been particularly shown and described with reference to some example embodiments thereof, it will be understood that various changes in form and details may be made therein without departing from the spirit and scope of the following claims.

What is claimed is:

1. A semiconductor package comprising:
a first semiconductor chip;
a sealing layer molding the first semiconductor chip; and
an upper connection structure on the sealing layer, wherein
the upper connection structure includes an insulating layer, the insulating layer including marking patterns defined by a first region and a second region, the first region being at at least a portion of the insulating layer and having a first light transmittance value, the second region being at at least a portion of the first region and having a second light transmittance value different from the first light transmittance value.

2. The semiconductor package of claim 1, wherein the insulating layer is a photo-imageable dielectric (PID) layer.

3. The semiconductor package of claim 1, wherein
the insulating layer includes a transparent material, and
the insulating layer and the first region have different colors from each other.

4. The semiconductor package of claim 1, wherein
a length of the first region in a horizontal direction is greater than a length of the second region in the horizontal direction,
a length of the first region in a vertical direction is different from a length of the second region in the vertical direction, and
the first region and the second region have different colors from each other.

5. The semiconductor package of claim 1, wherein the first region and the second region have different visible light transmittances from each other.

6. The semiconductor package of claim 1, wherein
a lowermost level of the first region is lower than a level of a top surface of the insulating layer, and
a lowermost level of the second region is lower than a lowermost level of the first region.

7. The semiconductor package of claim 1, wherein a lowermost level of the second region is higher than a lowermost level of the insulating layer.

8. The semiconductor package of claim 1, further comprising
a lower connection structure on a bottom surface of the first semiconductor chip and electrically connected to the first semiconductor chip, wherein
the lower connection structure includes
at least one lower insulating layer,
a lower redistribution pad arranged on the lower insulating layer, and
at least one lower via in contact with the lower redistribution pad.

9. The semiconductor package of claim 8, further comprising
an intermediate connection structure around the first semiconductor chip and electrically connected to the lower connection structure, wherein
the intermediate connection structure includes
at least one intermediate via configured to provide connection between the lower connection structure and the upper connection structure, and
at least one intermediate insulating layer through which the at least one intermediate via passes.

10. The semiconductor package of claim 1, further comprising:
an upper semiconductor package under the insulating layer; and
an inter-package connection member electrically connecting the upper semiconductor package to the upper connection structure, wherein
the upper semiconductor package includes
an uppermost connection structure, and
a second semiconductor chip on the uppermost connection structure.

11. A semiconductor package comprising:
a first semiconductor chip;
a sealing layer molding the first semiconductor chip;
an upper connection structure vertically spaced apart from a top surface of the first semiconductor chip;
a lower connection structure on a bottom surface of the first semiconductor chip and electrically connected to the first semiconductor chip;
an external connection terminal under the lower connection structure; and
an intermediate connection structure between the lower connection structure and the upper connection structure, wherein
the upper connection structure includes an insulating layer, the insulating layer including marking patterns defined by a first region and a second region, the first region being at at least a portion of the insulating layer and having a first light transmittance value, the second region being at at least a portion of the first region and having a second light transmittance value different from the first light transmittance value, a length of the first region in a horizontal direction being greater than a length of the second region in the horizontal direction, a length of the first region in a vertical direction being different from a length of the second region in the vertical direction, and
the lower connection structure includes
at least one lower insulating layer,
a lower redistribution pad on the lower insulating layer, and
at least one lower via in contact with the lower redistribution pad.

12. The semiconductor package of claim 11, wherein the insulating layer and the first region have different colors from each other.

13. The semiconductor package of claim 11, wherein
the first region and the second region have different colors from each other, and
the first region and the second region have different visible light transmittances from each other.

14. The semiconductor package of claim 11, wherein
a lowermost level of the first region is lower than a level of a top surface of the insulating layer,
a lowermost level of the second region is lower than a lowermost level of the first region, and
a lowermost level of the second region is higher than a lowermost level of the insulating layer.

15. The semiconductor package of claim 11, wherein the intermediate connection structure includes:
a plurality of conductive posts surrounding the first semiconductor chip; and
a plurality of chip connection terminals between the first semiconductor chip and the lower connection structure, wherein
the conductive posts each include a conductive material including copper (Cu), gold (Au), silver (Ag), nickel (Ni), tungsten (W), aluminum (Al), or a combination thereof.

16. The semiconductor package of claim 11, wherein the second region is a region defined after the first region.

17. The semiconductor package of claim 11, wherein the intermediate connection structure includes:
at least one intermediate via configured to provide connection between the lower connection structure and the upper connection structure;
at least one intermediate insulating layer through which the at least one intermediate via passes; and
a plurality of intermediate pattern layers on the intermediate insulating layer and connected to each other by the at least one intermediate via.

18. The semiconductor package of claim 11, wherein the insulating layer is a PID layer including a transparent material.

19. A semiconductor package comprising:
a first semiconductor chip;
a lower connection structure under the first semiconductor chip and electrically connected to the first semiconductor chip;
a solder ball under the lower connection structure;
a pad under the first semiconductor chip and electrically connected to the first semiconductor chip;
a conductive post surrounding the first semiconductor chip;
a sealing layer molding the first semiconductor chip and the conductive post;
an upper connection structure vertically spaced apart from a top surface of the first semiconductor chip; and
an intermediate connection structure between the lower connection structure and the upper connection structure, wherein
the upper connection structure includes an insulating layer, the insulating layer being a photo-imageable dielectric (PID) layer including a transparent material, the insulating layer including masking patterns defined by a first region and a second region, the first region being at at least a portion of the insulating layer and having a first light transmittance value, the second region being at at least a portion of the first region and having a second light transmittance value different from the first light transmittance value,
an upper semiconductor package is under the insulating layer, the upper semiconductor package including
an uppermost connection structure, and
a second semiconductor chip on the uppermost connection structure, and
an inter-package connection member electrically connects the upper semiconductor package with the upper connection structure.

20. The semiconductor package of claim 19, wherein
a length of the first region in a horizontal direction is greater than a length of the second region in the horizontal direction,
a length of the first region in a vertical direction is different from a length of the second region in the vertical direction,
a lowermost level of the first region is lower than a level of a top surface of the insulating layer,
a lowermost level of the second region is lower than a lowermost level of the first region, and
a lowermost level of the second region is higher than a lowermost level of the insulating layer.
